(19) United States
(12) Patent Application Publication
(10) Pub. No.: US 2026/0129936 A1
(43) Pub. Date: May 7, 2026

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Hong-Chih CHEN, Changhua County (TW); Ta-Chun LIN, Hsinchu (TW); Ming-Heng TSAI, Taipei City (TW); Zi-Xuan YOU, Hsinchu City (TW); Jhon-Jhy LIAW, Zhudong Township, Hsinchu County (TW)

(21) Appl. No.: 18/937,381

(22) Filed: Nov. 5, 2024

(51) Int. Cl. H01L 29/66; H01L 29/06; H01L 29/423; H01L 29/775; H01L 29/786

(52) U.S. Cl. CPC H10D 64/018; H10D 30/014; H10D 30/43; H10D 30/6735; H10D 30/6757; H10D 62/121; H10D 64/017; H10D 64/021; H10D 30/6736

(57) ABSTRACT

A method for forming a semiconductor device structure includes forming fin structures with a stack of alternating first semiconductor layers and second semiconductor layers over a substrate. The method also includes forming a gate structure across the fin structure. The method also includes recessing the first semiconductor layers to form first openings between the second semiconductor layers. The method also includes forming first inner spacers in the first openings. The method also includes removing the fin structures exposed from the gate structure to form a source/drain opening. The method also includes recessing the first semiconductor layers to form second openings between the second semiconductor layers. The method also includes forming second inner spacers in the second openings.

### BACKGROUND

Semiconductor devices are used in a variety of electronic applications, such as personal computers, cell phones, digital cameras, and other electronic equipment. Semiconductor devices are typically fabricated by sequentially depositing insulating or ILD structures, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure which can extend around the channel region providing access to the channel on two or four sides. GAA devices are compatible with conventional complementary metal-oxide-semiconductor (CMOS) processes.

However, the integration of fabrication of the GAA features around the nanowire can be challenging. While the current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1E, 1F, 1G, 1H, 1I, 1J, 1K are perspective representations of various stages of forming a semiconductor device structure, in accordance with some embodiments of the disclosure.

FIGS. 1E-1, 1F-1, 1G-1, 1H-1, 1I-1, 1J-1 are enlarged perspective representations of various stages of forming a semiconductor device structure, in accordance with some embodiments of the disclosure.

FIG. 2 is an enlarged top view of a semiconductor device structure, in accordance with some embodiments of the disclosure.

FIGS. 3A-3C are perspective representations of various stages of forming a semiconductor device structure, in accordance with some embodiments of the disclosure.

FIGS. 4A and 4B are perspective representations of various stages of forming a semiconductor device structure, in accordance with some embodiments of the disclosure.

FIG. 4A-1 is an enlarged perspective representation of a semiconductor device structure, in accordance with some embodiments of the disclosure.

FIGS. 5A, 5B and 5C are perspective representations of various stages of forming a semiconductor device structure, in accordance with some embodiments of the disclosure.

FIGS. 5A-1 and 5B-1 is an enlarged perspective representation of a semiconductor device structure, in accordance with some embodiments of the disclosure.

FIGS. 6A and 6B are perspective representations of various stages of forming a semiconductor device structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The nanostructure transistor (e.g. nanosheet transistor, nanowire transistor, multi-bridge channel, nano-ribbon FET, forksheet structures, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructures.

Embodiments for forming a semiconductor device structure are provided. The method for forming the semiconductor device structure may include forming multiple inner spacers between gate structures and the source/drain epitaxial structures. The source/drain epitaxial structures may not be damaged, and the capacitance may be reduced.

The semiconductor device structure may include various active devices. For example, the semiconductor device structure may include gate all around (GAA) structures. The semiconductor device structure may also include channel structures such as nanosheet structures, forksheet structures, and CFET structures. The semiconductor device structure may also include FinFET structures, or Si and SiGe planar transistors. The semiconductor device structure may include a gate blocking structure.

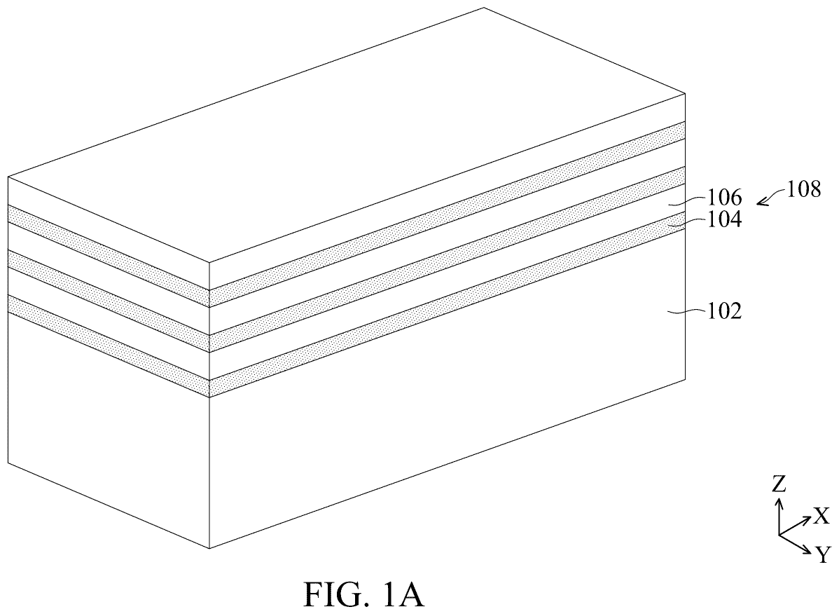

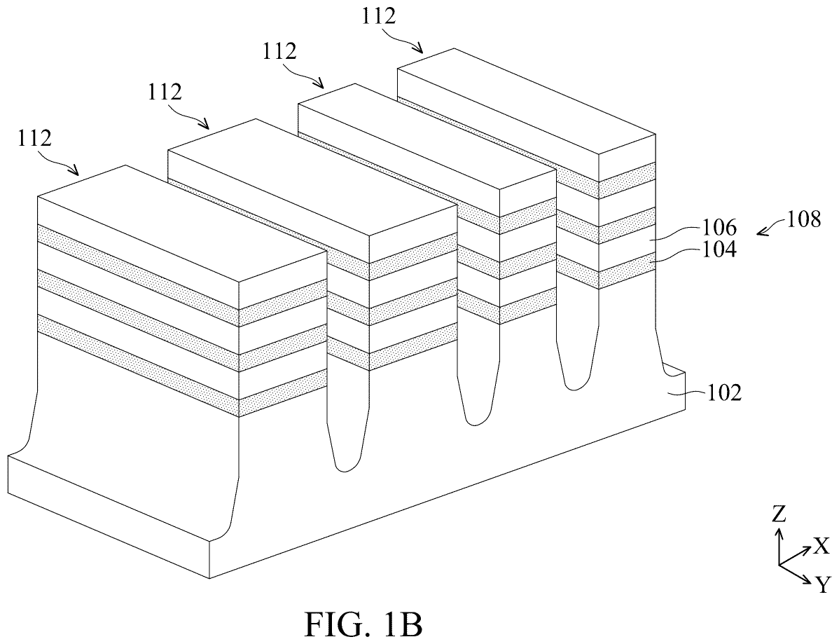

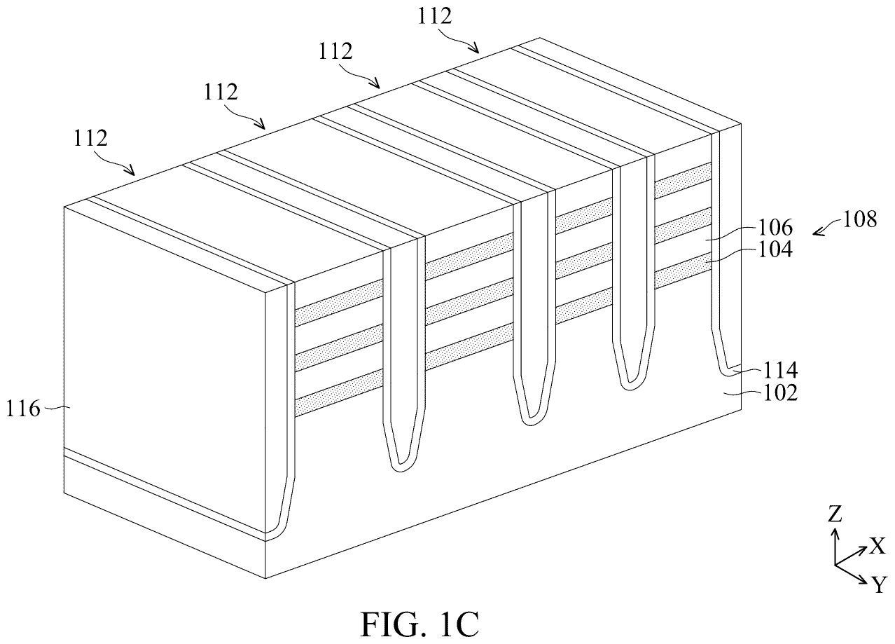

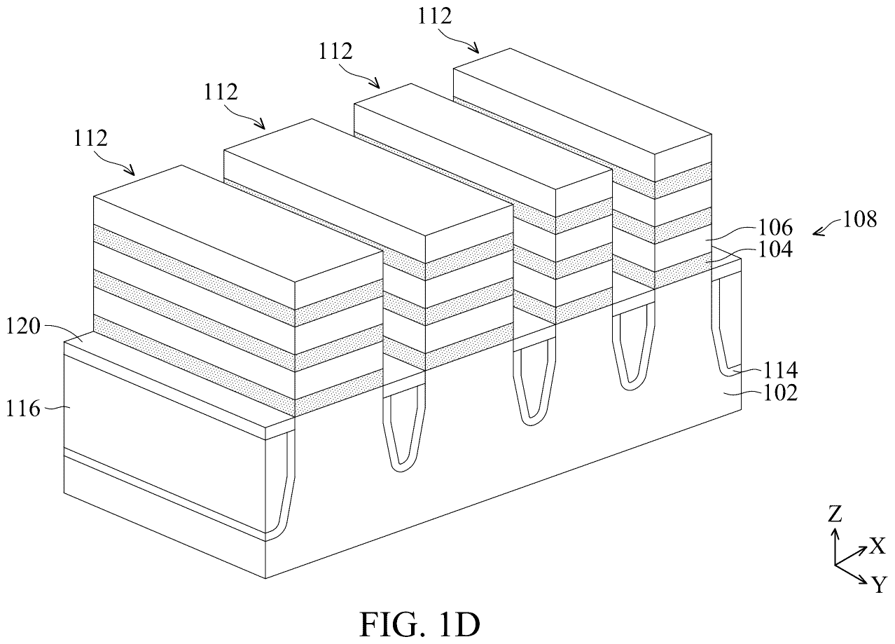

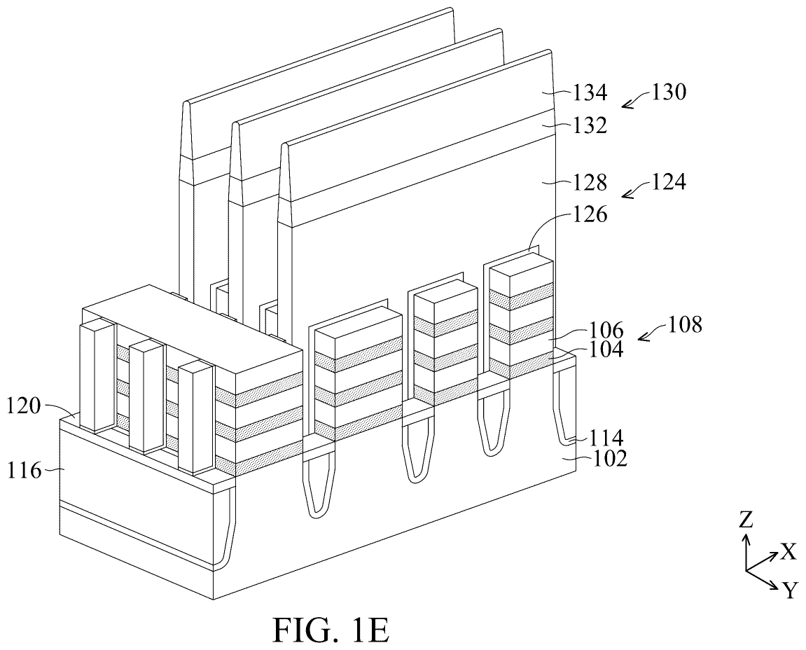

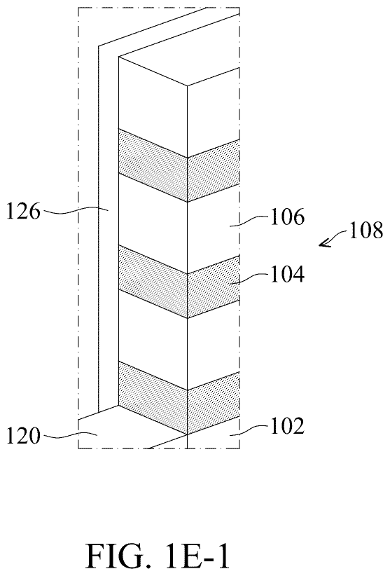

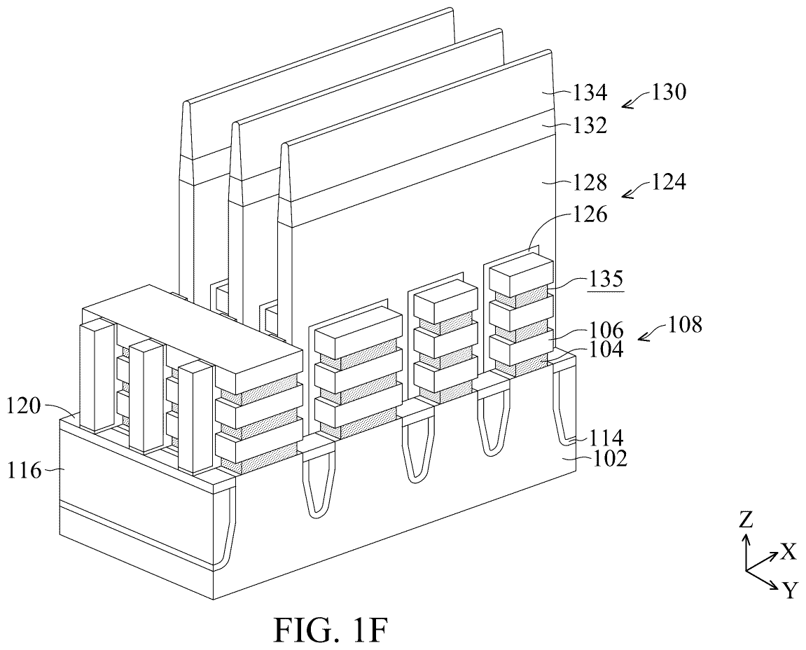

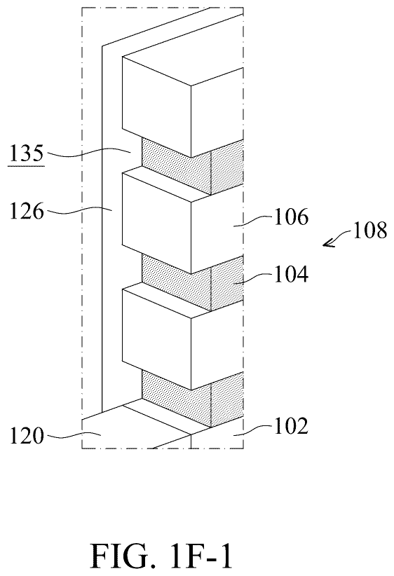

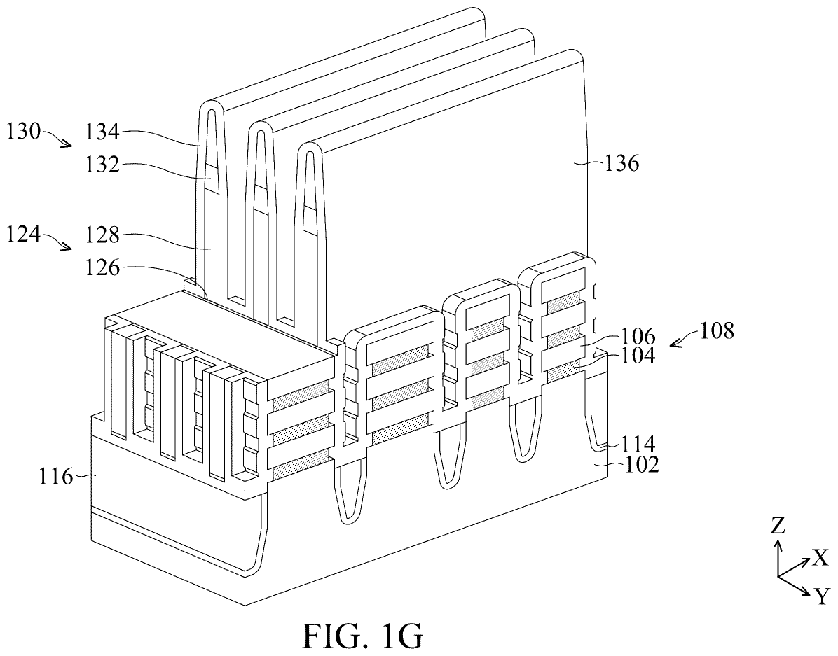

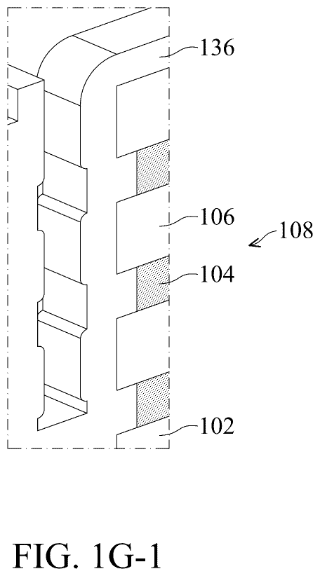

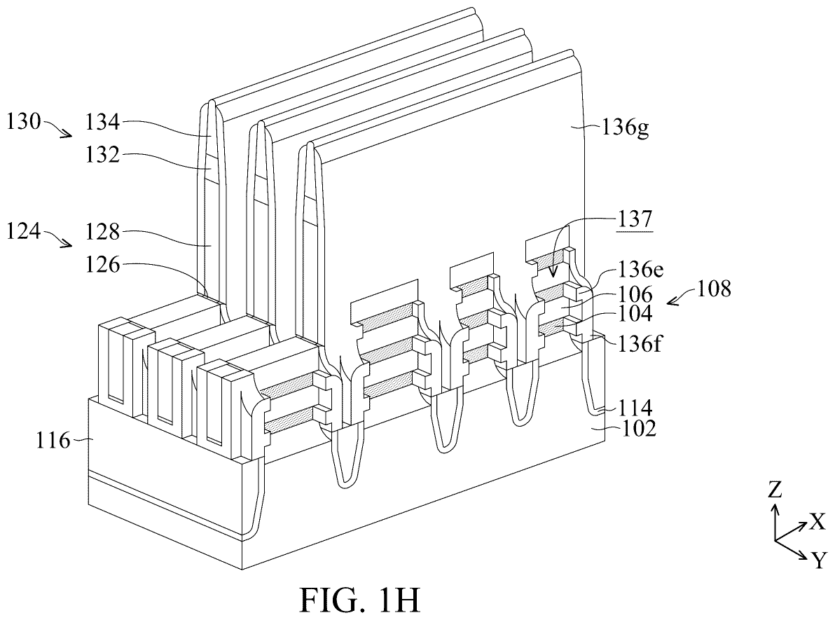

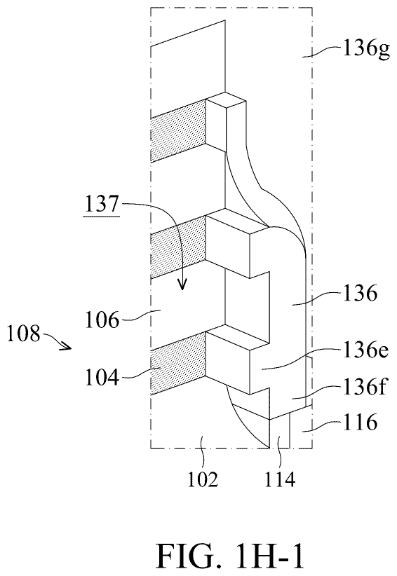

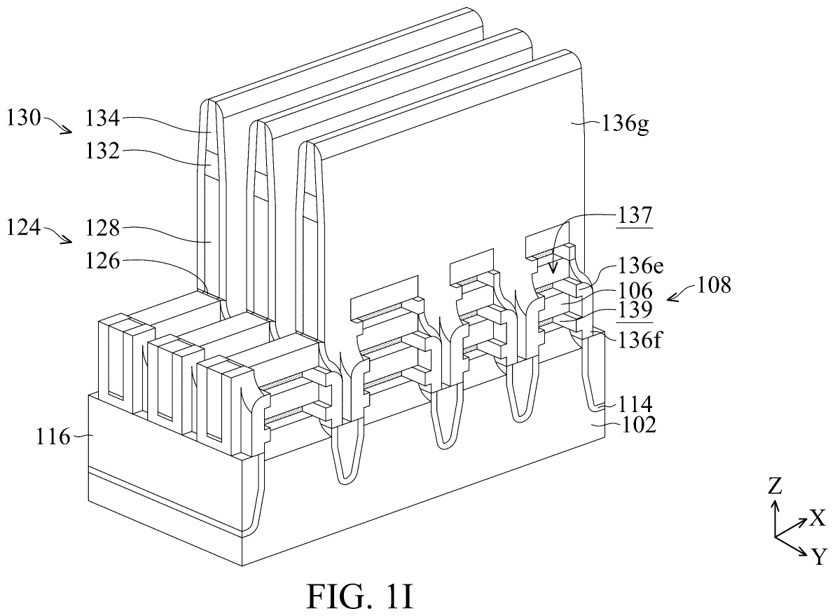

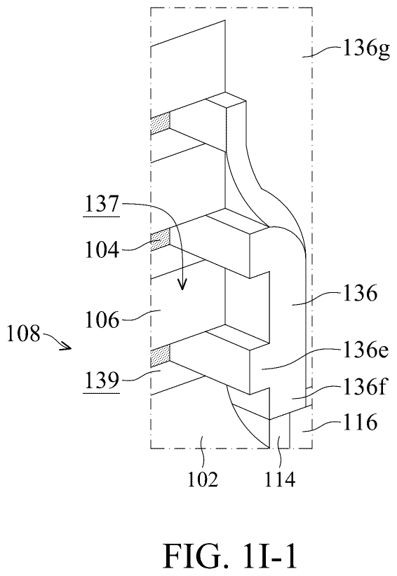

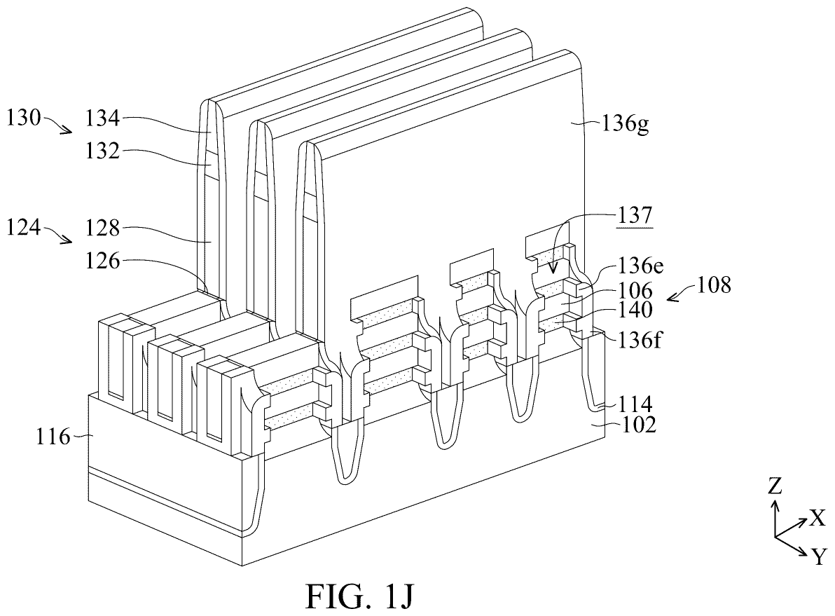

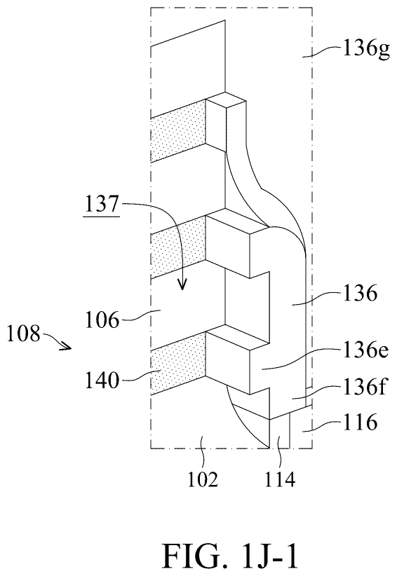

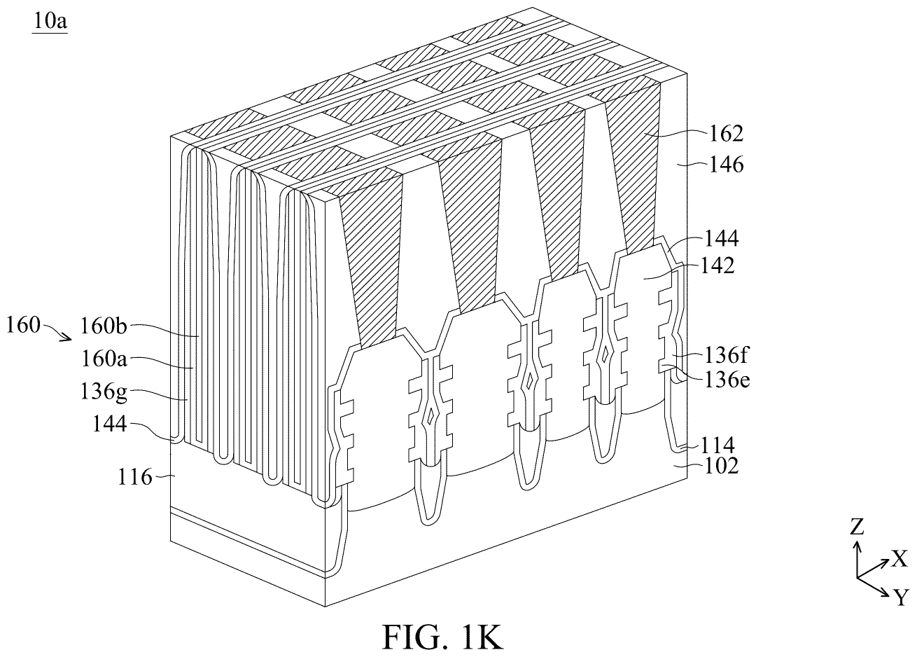

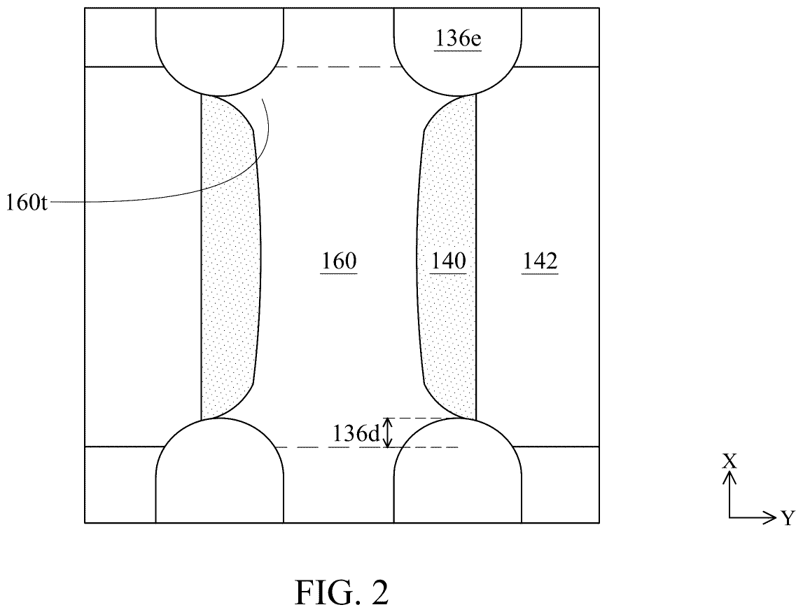

The semiconductor device structure 10a may be a nanostructure transistor. FIGS. 1A-1E, 1F, 1G, 1H, 1I, 1J, 1K are perspective representations of various stages of forming a semiconductor device structure 10a, in accordance with some embodiments of the disclosure. FIGS. 1E-1, 1F-1, 1G-1, 1H-1, 1I-1, 1J-1 are enlarged perspective representations of various stages of forming a semiconductor device structure 10a, in accordance with some embodiments of the disclosure. FIG. 2 is an enlarged top view of a semiconductor device structure 10a, in accordance with some embodiments of the disclosure.

A semiconductor stack 108 including first semiconductor material layers 104 and second semiconductor material layers 106 are formed over a substrate 102, as shown in FIG. 1A in accordance with some embodiments. The substrate 102 may be a semiconductor wafer such as a silicon wafer. The substrate 102 may also include other elementary semiconductor materials, compound semiconductor materials, alloy semiconductor materials, or a combination thereof. Examples of elementary semiconductor materials include, but are not limited to, crystal silicon, polycrystalline silicon, amorphous silicon, germanium, diamond, and combinations thereof. Examples of compound semiconductor materials include, but are not limited to, silicon carbide, gallium nitride, gallium arsenic, gallium phosphide, indium phosphide, indium arsenide, indium antimonide, and combinations thereof. Examples of alloy semiconductor materials include, but are not limited to, SiGe, GaAsP, AlInAs, AlGaAs, GaInAs, GaInP, GaInAsP, and combinations thereof. The substrate 102 may include an epitaxial layer. For example, the substrate 102 may be an epitaxial layer overlying a bulk semiconductor. In addition, the substrate 102 may also be semiconductor on insulator (SOI). The SOI substrate may be fabricated by a wafer bonding process, a silicon film transfer process, a separation by implantation of oxygen (SIMOX) process, other applicable methods, or a combination thereof. The substrate 102 may be an N-type substrate. The substrate 102 may be a P-type substrate.

Next, first semiconductor material layers 104 and second semiconductor material layers 106 are stacked in an alternating manner over the substrate 102 to form the semiconductor stack 108, as shown in FIG. 1A in accordance with some embodiments. The first semiconductor material layers 104 and the second semiconductor material layers 106 may include Si, Ge, SiGe, GaAs, InSb, GaP, GaSb, InAlAs, InGaAs, GaSbP, GaAsSb, or InP. The first semiconductor material layers 104 and second semiconductor material layers 106 may be made of different materials with different etching rates. In some embodiments, the first semiconductor material layers 104 are made of SiGe and the second semiconductor material layers 106 are made of Si.

The first semiconductor material layers 104 and second semiconductor material layers 106 may be formed by low pressure chemical vapor deposition (LPCVD) process, epitaxial growth process, other applicable methods, or a combination thereof. The epitaxial growth process may include molecular beam epitaxy (MBE), metal organic chemical vapor deposition (MOCVD), or vapor phase epitaxy (VPE).

It should be noted that, although there are three layers of the first semiconductor material layers 104 and three layers of the second semiconductor material layers 106 shown in FIG. 1A, the number of the first semiconductor material layers 104 and second semiconductor material layers 106 are not limited herein, depending on the demand of performance and process. For example, the semiconductor structure may include two to five layers of the first semiconductor material layers 104 and two to five layers of the second semiconductor material layers 106.

Next, a mask structure may be formed over the semiconductor stack 108. The mask structure may be a multilayer structure including a pad layer and a hard mask layer formed over the pad layer. The pad layer may be made of silicon oxide, which may be formed by thermal oxidation or CVD. The hard mask layer may be made of silicon nitride, which may be formed by CVD, such as LPCVD or plasma-enhanced CVD (PECVD).

After the first semiconductor material layers 104 and the second semiconductor material layers 106 are formed as the semiconductor stack 108 over the substrate 102, the semiconductor stack 108 is patterned to form fin structures 112 using the mask structure as a mask layer, as shown in FIG. 1B in accordance with some embodiments. The fin structures 112 may include base fin structures and the semiconductor stack 108, including the first semiconductor material layers 104 and the second semiconductor material layers 106, formed over the base fin structure.

The patterning process may include forming a mask structure over the first semiconductor material layers 104 and the second semiconductor material layers 106 and etching the semiconductor stack 108 and the underlying substrate 102 through the mask structure.

The patterning process of forming the fin structures 112 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

After the fin structures 112 are formed, liner layers 114 are formed over the fin structures 112 and in the trenches between the fin structures 112, as shown in FIG. 1C in accordance with some embodiments. The liner layers 114 may be conformally formed over the substrate 102, the fin structures 112, and the mask structure covering the fin structures 112. The liner layers 114 may be used to protect the fin structures 112 from being damaged in the following processes (such as an anneal process or an etching process). The liner layers 114 may be made of silicon nitride, silicon oxide, other suitable materials, or a combination thereof. The liner layers 114 may be formed using thermal oxidation, a CVD process, an atomic layer deposition (ALD) process, an LPCVD process, a plasma enhanced CVD (PECVD) process, an HDPCVD process, a flowable CVD (FCVD) process, another applicable process, or a combination thereof.

Next, an isolation material 116 is then filled into the trenches between the fin structures 112 and over the liner layers 114, as shown in FIG. 1C in accordance with some embodiments. The isolation material 116 may be made of silicon oxide, silicon nitride, silicon oxynitride (SiON), fluoride-doped silicate glass (FSG), other low-k dielectric materials, or a combination thereof. The isolation material 116 may be deposited by a deposition process, such as a chemical vapor deposition (CVD) process (e.g. a flowable CVD (FCVD) process), a spin-on-glass process, or another applicable process.

Next, the hard mask layer over the fin structures 112 may be removed, and the pad layer over the fin structures 112 may be exposed. The hard mask layer may be removed by performing a planarization process such as a chemical mechanical polishing (CMP) process.

Next, the isolation material 116 is etched back using an etching process, and an isolation structure 116 is formed surrounding the base fin structure, as shown in FIG. 1D in accordance with some embodiments. The etching process may be used to remove the top portion of the isolation material 116. The pad layer over the fin structure 112 may be removed in the etching process. As a result, the semiconductor stack 108 may be exposed. The isolation structure 116 may be a shallow trench isolation (STI) structure 116. The isolation structure 116 may be configured to electrically isolate active regions such as fin structures 112 of the semiconductor structure 10a and prevent electrical interference and crosstalk.

Later, a hard mask layer 120 is formed over the isolation structure 116, as shown in FIG. 1D in accordance with some embodiments. The hard mask layer 120 may be made of SiN, SiCON, SiCO, SiCN, SiON, AlN, other dielectric material with low dielectric constant (for example, dielectric constant less than 7), or a combination thereof.

The hard mask layer 120 may be formed over the fin structures 112 and the isolation structures 116 first, and then the hard mask layer 120 formed over the top surfaces and the sidewalls of the fin structures 112 may be removed.

Next, a dummy gate structure 124 is formed over and across the fin structures 112, as shown in FIG. 1E in accordance with some embodiments. The dummy gate structure 124 may be used to define the source/drain regions and the channel regions of the resulting semiconductor structure 10a. The dummy gate structure 124 may include a dummy gate dielectric layer 126 and a dummy gate electrode layer 128. The dummy gate dielectric layer 126 and the dummy gate electrode layer 128 may be replaced by the following steps to form a real gate structure with a high-k dielectric layer and a metal gate electrode layer.

It should be noted that, the leftmost fin structure 112 shown in FIG. 1E is cut off for clarity. It is merely an example to show the cross-section under the dummy gate structure 124, and the profile of the leftmost fin structure 112 remains the same as other fin structures 112.

The dummy gate dielectric layer 126 may include one or more dielectric materials, such as silicon oxide, silicon nitride, silicon oxynitride (SiON), HfO₂, HfZrO, HfSiO, HfTiO, HfAlO, or a combination thereof. The dummy gate dielectric layer 126 may be formed by an oxidation process (e.g., a dry oxidation process, or a wet oxidation process), a chemical vapor deposition process, other applicable processes, or a combination thereof. Alternatively, the dummy gate dielectric layer 126 may include a high-k dielectric layer (e.g., the dielectric constant is greater than 3.9) such as hafnium oxide (HfO₂). Alternatively, the high-k dielectric layer may include other high-k dielectrics, such as LaO, AlO, ZrO, TiO, Ta₂O₅, Y₂O₃, SrTiO₃, BaTiO₃, BaZrO, HfZrO, HfLaO, HfTaO, HfSiO, HfSiON, HfTiO, LaSiO, AlSiO, (Ba, Sr)TiO₃, Al₂O₃, other applicable high-k dielectric materials, or a combination thereof. The high-k dielectric layer may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

The dummy gate electrode layer 128 may include polycrystalline-silicon (poly-Si), poly-crystalline silicon-germanium (poly-SiGe), other applicable materials, or a combination thereof. The dummy gate electrode layer 128 may be formed by a chemical vapor deposition process (e.g., a low pressure chemical vapor deposition process, or a plasma enhanced chemical vapor deposition process), a physical vapor deposition process (e.g., a vacuum evaporation process, or a sputtering process), other applicable processes, or a combination thereof.

Next, a hard mask layer 130 is formed over the dummy gate structure 124, as shown in FIG. 1E in accordance with some embodiments. The hard mask layer 130 may include multiple layers, such as an oxide layer 132 and a nitride layer 134. In some embodiments, the oxide layer 132 includes silicon oxide, and the nitride layer 134 includes silicon nitride.

The formation of the dummy gate structure 124 may include conformally forming a dielectric material as the dummy gate dielectric layer 126. Afterwards, a conductive material may be formed over the dielectric material as the dummy gate electrode layer 128. The hard mask layer 130, including the oxide layer 132 and the nitride layer 134, may be formed over the conductive material. Next, the dielectric material and the conductive material may be patterned and etched through the hard mask layer 130 to form the dummy gate structure 124, as shown in FIG. 1E in accordance with some embodiments. The dummy gate dielectric layer 126 and the dummy gate electrode layer 128 may be etched by a dry etching process. After the etching process, the first semiconductor material layers 104 and the second semiconductor material layers 106 may be exposed at opposite sides of the dummy gate structure 124.

Next, the first semiconductor material layers 104 is laterally recessed in the X-direction, and recesses 135 are formed between the second semiconductor material layers 106, as shown in FIGS. 1F and 1F-1 in accordance with some embodiments. The outer portions of the first semiconductor material layers 104 may be removed, and the inner portions of the first semiconductor material layers 104 under the second semiconductor material layers 106 may remain. After the lateral etching process, the sidewalls of the etched first semiconductor material layers 104 may be not aligned with the sidewalls of the second semiconductor material layers 106.

The lateral etching of the first semiconductor material layers 104 may be a dry etching process, a wet etching process, or a combination thereof. In some embodiments, the first semiconductor material layers 104 are Ge or SiGe and the second semiconductor material layers 106 are Si, and the first semiconductor material layers 104 are selectively etched to form the recesses by using a wet etchant such as, but not limited to, ammonium hydroxide (NH₄OH), tetramethylammonium hydroxide (TMAH), ethylenediamine pyrocatechol (EDP), or potassium hydroxide (KOH) solutions, or the like.

Next, a conformal spacer layer 136 is formed over the fin structures 112 and the dummy gate structure 124, as shown in FIGS. 1G and 1G-1 in accordance with some embodiments. In some embodiments, the spacer layer 136 is also formed in the recesses 135. The spacer layer 136 may be made of silicon oxide, silicon nitride, silicon oxynitride, silicon carbon oxynitride, other dielectric materials, or a combination thereof. The spacer layer 136 may be formed by a chemical vapor deposition (CVD) process, a spin-on-glass process, or another applicable process.

Later, the first semiconductor material layers 104 and the second semiconductor material layers 106 of the fin structures 112 not covered by the dummy gate structure 124 are etched to form the source/drain opening 137 beside the dummy gate structure 124. A recess may be formed in the isolation structure 116 when etching the first semiconductor material layers 104 and the second semiconductor material layers 106 of the fin structures 112.

The fin structures 112 may be etched by performing a number of etching processes. That is, the first semiconductor material layers 104 and the second semiconductor material layers 106 of the fin structures 112 may be etched in different etching processes. The etching process may be a dry etching process or a wet etching process. The fin structures 112 may be etched by a dry etching process.

After etching the fin structures 112, a pair of gate spacer layers 136g is formed over opposite sidewalls of the dummy gate structure 124, and a pair of fin spacer layers 136f is formed over opposite sides of the bottom portion of the source/drain opening 137, as shown in FIGS. 1H and 1H-1 in accordance with some embodiments. The top surface of the hard mask layer 130 may be exposed after etching the fin structures 112. In some embodiments, the fin spacer layers 136f have extending portions 136e exposed in the source/drain opening 137.

The extending portions 136e of the fin spacer layers 136f formed between the second semiconductor material layers 106 may be referred as first inner spacers 136e. In some embodiments, the first inner spacers 136e are formed over opposite sides of the first semiconductor material layers 104 in the X-direction.

Next, the first semiconductor material layers 104 may be laterally etched from the source/drain opening 137 to form recesses 139, as shown in FIGS. 1I and 1I-1 in accordance with some embodiments. The processes for forming recesses 139 may be the same as, or similar to, those used to form the recesses 135. For the purpose of brevity, the descriptions of these processes are not repeated herein.

Next, a second inner spacer 140 may be formed in the recess 139, as shown in FIGS. 1J and 1J-1 in accordance with some embodiments. The second inner spacer 140 may provide a barrier between subsequently formed source/drain epitaxial structures and gate structure. The second inner spacer 140 may be made of a dielectric material such as silicon oxide (SiO₂), silicon nitride (SiN), silicon carbide (SiC), silicon oxynitride (SiON), silicon carbon nitride (SiCN), silicon oxide carbonitride (SiOCN), SiCO, SiO2:F, oxide, nitrogen, carbon-based materials, or a combination thereof. The second inner spacer 140 may be formed using a deposition process. The deposition process may include a CVD process (such as LPCVD, PECVD, SACVD, or FCVD), an ALD process, another applicable method, or a combination thereof.

In some embodiments, the first inner spacer 136e covers the sidewalls of the second inner spacer 140. In some embodiments, the dielectric constant of the first inner spacer 136e is less than the dielectric constant of the second inner spacer 140. The capacitance may be lower.

In some embodiments, the dielectric constant of the first inner spacer 136e is greater than the dielectric constant of the second inner spacer 140. The hardness of the first inner spacer 136e may be greater than the hardness of the second inner spacer 140, and the etching resistance may be enhanced.

Next, a source/drain epitaxial structure 142 is formed in the source/drain opening 137, as shown in FIG. 1K in accordance with some embodiments. The source/drain epitaxial structure 142 may be formed over opposite sides of the dummy gate structure 124. The source/drain epitaxial structure 142 may refer to a source or a drain, individually or collectively dependent upon the context.

A strained material may be grown in the source/drain opening using an epitaxial (epi) process to form the source/drain epitaxial structure 142. In addition, the lattice constant of the strained material may be different from the lattice constant of the substrate 102. The source/drain epitaxial structure 142 may include SiGeB, SiP, SiAs, SiGe, other applicable materials, or a combination thereof. The source/drain epitaxial structure 142 may be formed by an epitaxial growth step, such as metalorganic chemical vapor deposition (MOCVD), metalorganic vapor phase epitaxy (MOVPE), plasma-enhanced chemical vapor deposition (PECVD), remote plasma-enhanced chemical vapor deposition (RP-CVD), molecular beam epitaxy (MBE), hydride vapor phase epitaxy (HVPE), liquid phase epitaxy (LPE), chloride vapor phase epitaxy (Cl-VPE), or any other suitable method.

The source/drain epitaxial structure 142 may be in-situ doped during the epitaxial growth process. For example, the source/drain epitaxial structure 142 may be the epitaxially grown SiGe doped with boron (B). For example, the source/drain epitaxial structure 142 may be the epitaxially grown Si doped with carbon to form silicon: carbon (Si:C) source/drain features, phosphorous to form silicon:phosphor (Si:P) source/drain features, or both carbon and phosphorous to form silicon carbon phosphor (SiCP) source/drain features. The source/drain epitaxial structure 142 may be doped in one or more implantation processes after the epitaxial growth process.

Next, an etch stop layer 144 may be formed over the source/drain epitaxial structures 142, as shown in FIG. 1K in accordance with some embodiments. More specifically, the etch stop layer 144 may cover the sidewalls of the gate spacer layers 136g and the fin spacer layers 136f, and the top surface of the source/drain epitaxial structure 142. The etch stop layer 144 may be made of a dielectric material such as silicon nitride, silicon oxide, silicon oxynitride (SiON), other applicable materials, or a combination thereof. The etch stop layer 144 may be formed by a chemical vapor deposition process (e.g., a plasma enhanced chemical vapor deposition (PECVD) process, or a metalorganic chemical vapor deposition (MOCVD) process), an atomic layer deposition (ALD) process (e.g., a plasma enhanced atomic layer deposition (PEALD) process), a physical vapor deposition (PVD) process (e.g., a vacuum evaporation process, or a sputtering process), other applicable processes, or a combination thereof.

After the etch stop layer 144 is formed, an inter-layer dielectric (ILD) structure 146 is formed over the etch stop layer 144 and the source/drain epitaxial structure 142, as shown in FIG. 1K in accordance with some embodiments. In some embodiments, the ILD structure 146 surrounds the source/drain epitaxial structure 142.

The ILD structure 146 may include multilayers made of multiple dielectric materials, such as silicon oxide (SiOₓ, where x may be a positive integer), silicon oxycarbide (SiCO_{y}, where y may be a positive integer), silicon oxycarbonitride (SiNCO_{z}, where z may be a positive integer), silicon nitride, silicon oxynitride, phosphosilicate glass (PSG), borophosphosilicate glass (BPSG), low-k dielectric material, or another applicable dielectric material. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The ILD structure 146 may be formed by chemical vapor deposition (CVD), physical vapor deposition (PVD), atomic layer deposition (ALD), spin-on coating, or another applicable process.

Afterwards, a planarizing process or an etch-back process may be performed on the ILD structure 146 until the top surface of the dummy gate structure 124 is exposed. After the planarizing process, the top surface of the dummy gate structure 124 may be substantially level with the top surfaces of the gate spacer layer 136g and the ILD structure 146. The planarizing process may include a grinding process, a chemical mechanical polishing (CMP) process, an etching process, other applicable processes, or a combination thereof.

Next, the first semiconductor material layers 104 may be removed and gaps may be formed between the second semiconductor material layers 106. More specifically, the second semiconductor material layers 106 exposed by the gaps may be referred as the nanostructures 106, and the nanostructures 106 are configured to function as channel regions 106 in the resulting semiconductor devices 10a in accordance with some embodiments.

The first semiconductor material layers 104 may be removed by performing one or more etching processes. The etching process may include a selective wet etching process, such as APM (e.g., ammonia hydroxide-hydrogen peroxide-water mixture) etching process. The wet etching process uses etchants such as ammonium hydroxide (NH₄OH), TMAH, ethylenediamine pyrocatechol (EDP), potassium hydroxide (KOH) solutions, or a combination thereof.

Next, gate structures 160 are formed surrounding the nanostructures 106 and over the nanostructures 106, as shown in FIG. 1K in accordance with some embodiments. The gate structures 160 are formed surrounding the nanostructures 106 to form gate-all-around (GAA) transistor structures. Therefore, the gate control ability may be enhanced. In some embodiments, the gate structure 160 is formed between adjacent gate spacer layers 136g. In some embodiments, the first inner spacers 136e and the second inner spacers 140 are formed between the gate structure 160 and the source/drain epitaxial structures 142.

In some embodiments as shown in FIG. 1K, the gate structures 160 are multi-layered structures. Each of the gate structures 160 may include an interfacial layer, a gate dielectric layer 160a, a work function layer 160b, and a gate electrode layer.

The interfacial layer may be formed around the nanostructures 106 and on the exposed portions of the base fin structures. The interfacial layer may be made of silicon oxide, and the interfacial layer may be formed by thermal oxidation.

The gate dielectric layer 160a may be formed over the interfacial layer, so that the nanostructures 106 are surrounded (e.g. wrapped) by the gate dielectric layer 160a. In addition, the gate dielectric layer 160a also may cover the sidewalls of the gate spacer layer 136g, the first inner spacer 136e, and the second inner spacer. The gate dielectric layer 160a may be made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, other applicable high-k dielectric materials, or a combination thereof. The gate dielectric layer 160a may be formed using CVD, ALD, other applicable methods, or a combination thereof. In some embodiments, a portion of the first inner spacer 136e and the second inner spacer 140 are in direct contact with the gate dielectric layer 160a.

The work function layers 160b may be conformally formed over the nanostructure 106. The work function layers 160b may be multi-layer structures. The work function layers 160b may be made of a metal material. The metal material of the work function layers 160b may include an N-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), or a combination thereof. The metal material of the work function layer 160b may include a P-work-function metal. The P-work-function metal may include titanium nitride (TiN), tungsten nitride (WN), tantalum nitride (TaN), ruthenium (Ru) or a combination thereof. The work function layers 160b may be formed by using CVD, ALD, other applicable methods, or a combination thereof.

Next, a gate electrode layer may be formed over the work function layer 160b. The gate electrode layer may be made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. The gate electrode layer may be formed using CVD, ALD, electroplating, another applicable method, or a combination thereof. After the gate electrode layer is formed, a planarization process such as CMP or an etch-back process may be performed.

Next, an opening may be formed in the ILD structure 146 over the source/drain epitaxial structures 142. A barrier layer may be conformally formed over the bottom surface and the sidewalls of the opening. The barrier layer may be formed before filling the conductive material in the opening to prevent the conductive material from diffusing out. The barrier layer may also serve as an adhesive or glue layer. The material of the barrier layer may be TiN, Ti, other applicable materials, or a combination thereof. The barrier layer may be formed by depositing the barrier layer materials by a physical vapor deposition process (PVD) (e.g., evaporation or sputtering), an atomic layer deposition process (ALD), an electroplating process, other applicable processes, or a combination thereof.

Next, a silicide structure may be formed in the source/drain epitaxial structure 142. The silicide structure may reduce the contact resistance between the source/drain epitaxial structure 142 and the subsequently formed contact structure over the source/drain epitaxial structure 142.

The silicide structure may be made of TiSi, Ti₅Si₄, TiSi₂, NiSi, NiSi₂, CoSi, CoSi₂, WSi₂ and MoSi₂, or other suitable low-resistance materials. The silicide structure may be formed over the source/drain epitaxial structure 142 by forming a metal layer over the source/drain epitaxial structure 142 first. The metal layer may react with the source/drain epitaxial structure 142 in an annealing process and a silicide layer may be produced. Afterwards, the unreacted metal layer may be removed in an etching process and the silicide structure may be formed over the source/drain epitaxial structure 142.

Afterwards, a contact structure 162 is formed into the opening over the first source/drain epitaxial structure 142, as shown in FIG. 1K in accordance with some embodiments. The contact structure 162 may be made of a metal material (e.g., Co, Ni, W, Ti, Ta, Cu, Al, Ru, Mo, TiN, TaN, and/or a combination thereof), metal alloys, poly-Si, other applicable conductive materials, or a combination thereof. The contact structure 162 may be formed by a CVD process, a PVD process, an ALD, an electroplating process, another suitable process, or a combination thereof to deposit the conductive materials of the contact structure 162, and then a planarization process such as a chemical mechanical polishing (CMP) process or an etch back process is optionally performed to remove excess conductive materials. After the planarization process, the top surface of the contact structure 162 may be level with the top surface of the gate spacer layer 136g.

FIG. 2 is an enlarged top view of the semiconductor device structure 10a, in accordance with some embodiments of the disclosure. In some embodiments, the gate structure 160 has a tip portion 160t sandwiched between the first inner spacer 136e and the second inner spacer 140. In some embodiments, the gate structure 160 is between adjacent first inner spacers 136e and adjacent second inner spacers 140.

In some embodiments, the second inner spacer 140 and the first inner spacer 136e have different widths in the Y-direction. In some embodiments, the first inner spacer 136e is wider than the second inner spacer 140 in the Y-direction.

In some embodiments, the end portion of the second inner spacer 140 is thinner than the middle portion of the second inner spacer 140. In some embodiments, the source/drain epitaxial structure 142 is wider than the second inner spacer 140 in the X-direction. In some embodiments, the sidewall of the end portion of the second inner spacer 140 is misaligned with the sidewall of the gate structure 160. Therefore, the sidewall of the source/drain epitaxial structure 142 is misaligned with the sidewall of the second inner spacer 140, and the source/drain epitaxial structure 142 may not be damaged at the sidewalls of the second inner spacer 140.

In some embodiments, the distance 136d of the sidewall of the first inner spacer 136e protruding from the sidewall of fin structure 112 is in a range of about 2 nm to about 5 nm. If the distance 136d is too great, the dummy gate structure 124 may also be consumed during forming the recesses 135. If the distance 136d is too less, the source/drain epitaxial structure 142 may be damaged.

By forming multiple inner spacers 136e and 140 between the gate structure 160 and the source/drain epitaxial structure 142, the source/drain epitaxial structure 142 may not be damaged. In addition, the capacitance may be reduced with the first inner spacers 136e.

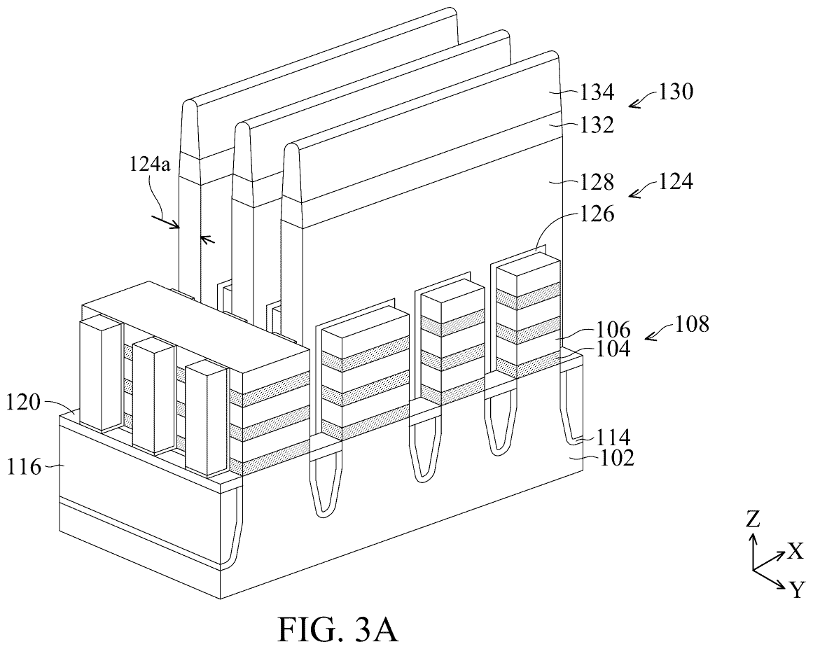

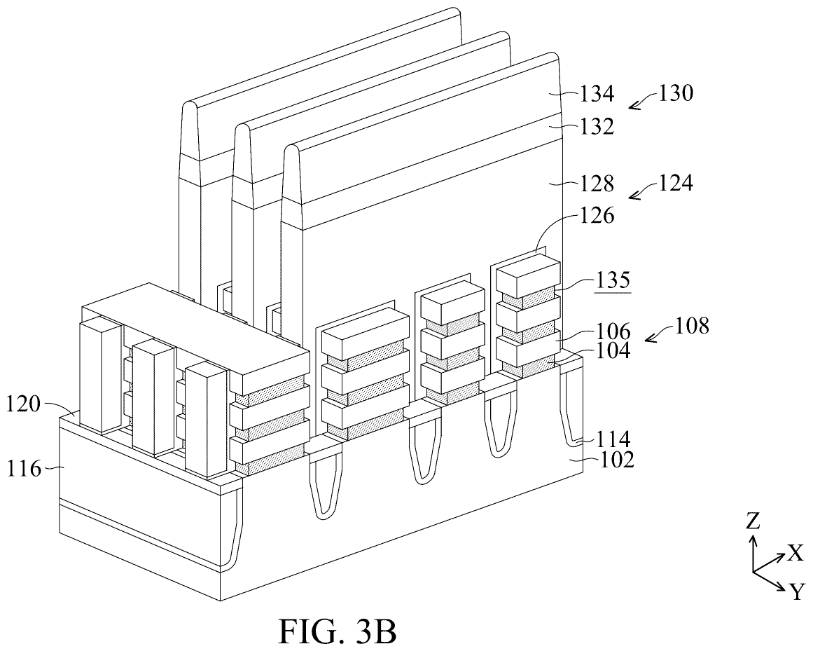

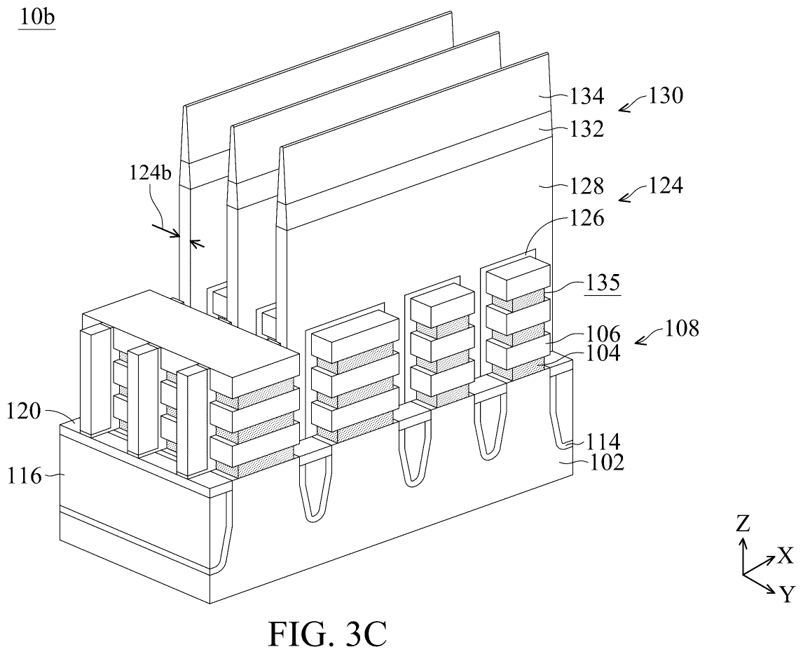

Many variations and/or modifications may be made to the embodiments of the disclosure. FIGS. 3A-3C are perspective representations of various stages of forming a semiconductor device structure 10b, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 3A-3C in accordance with some embodiments, the dummy gate structure 124 are formed in multiple processes.

The dummy gate structure 124 may be formed with a width 124a first, as shown in FIG. 3A in accordance with some embodiments. Later, the first semiconductor layers 104 are recessed in the X-direction, and the recesses 135 are formed, as shown in FIG. 3B in accordance with some embodiments. Afterwards, the dummy gate structure 124 is etched again, and the width 124b of the dummy gate structure 124 is reduced to a target value. In some embodiments, the width 124b of the dummy gate structure 124 after forming the recesses 135 is less than the width 124a of the dummy gate structure 124 before forming the recesses 135. Since the dummy gate structure 124 may be consumed when forming the recesses 135, the width 124b of the dummy gate structure 124 may be more precisely controlled by multiple etching processes of forming the dummy gate structure 124.

By forming multiple inner spacers 136e and 140 between the gate structure 160 and the source/drain epitaxial structure 142, the source/drain epitaxial structure 142 may not be damaged. In addition, the capacitance may be reduced with the first inner spacers 136e. The width of the dummy gate structure 124 may be precisely controlled by multiple etching processes before and after forming the recesses 135.

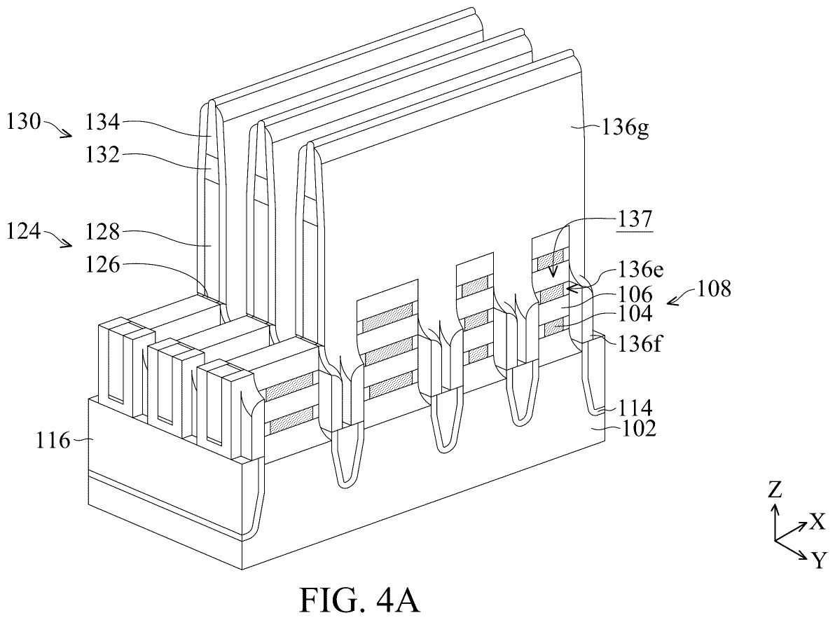

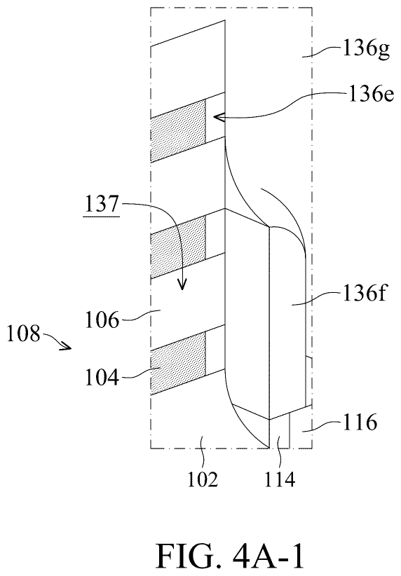

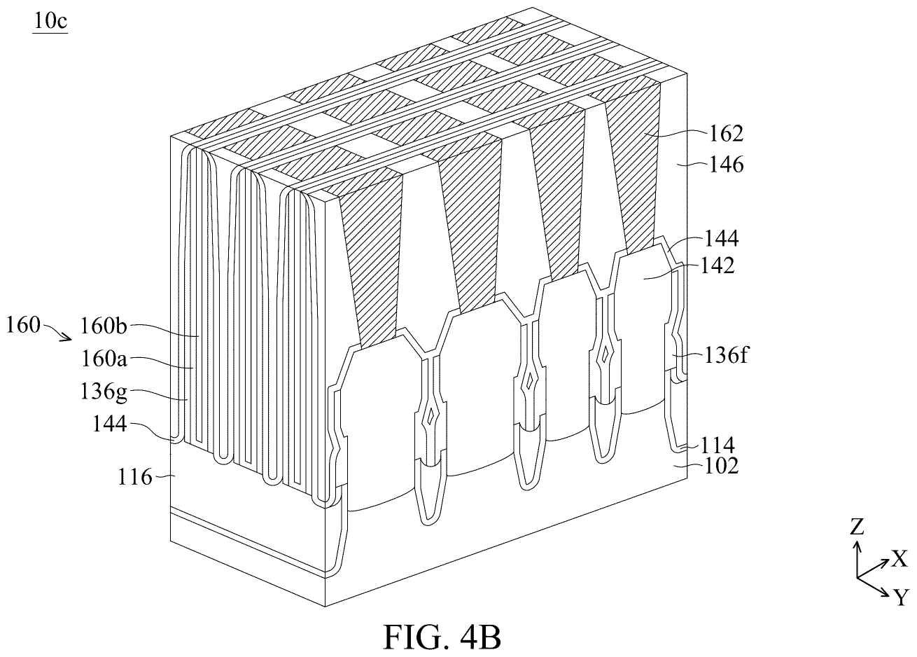

Many variations and/or modifications may be made to the embodiments of the disclosure. FIGS. 4A-4B are perspective representations of various stages of forming a semiconductor device structure 10c, in accordance with some embodiments of the disclosure. Some processes or devices are the same as, or similar to, those described in the embodiments above, and therefore the descriptions of these processes and devices are not repeated herein. The difference from the embodiments described above is that, as shown in FIG. 4A in accordance with some embodiments, the extending portions 136e of the spacer layer 136 exposed in the source/drain opening 137 are trimmed.

An etching process may be performed to remove the extending portions 136e of the fin spacer layer 136f, as shown in FIGS. 4A and 4A-1 in accordance with some embodiments. In some embodiments, the extending portions 136e over opposite sides of the first semiconductor material layers 104 remain. In some embodiments, the first inner spacers 136e are formed over opposite sides of the first semiconductor material layers 104 are exposed. The fin spacer layer 136f may have a flat sidewall after the etching process. Therefore, it may be easier to grow the source/drain epitaxial structure 142 in the source/drain opening 137, as shown in FIG. 4B in accordance with some embodiments, and the quality of the source/drain epitaxial structure 142 may be better.

By forming multiple inner spacers 136e and 140 between the gate structure 160 and the source/drain epitaxial structure 142, the source/drain epitaxial structure 142 may not be damaged. In addition, the capacitance may be reduced with the first inner spacers 136e. By trimming the extending portions 136e of the fin spacer layer 136f, the quality of the source/drain epitaxial structure 142 may be better.

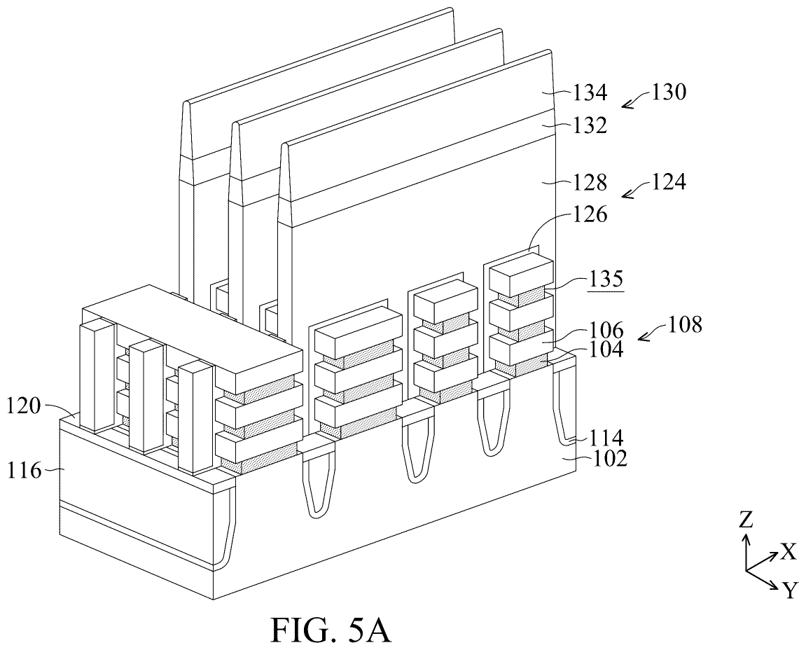

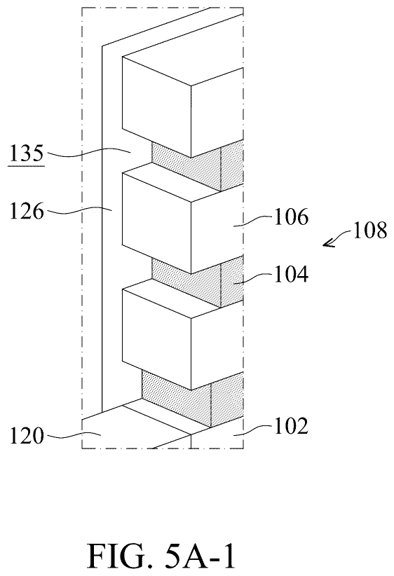

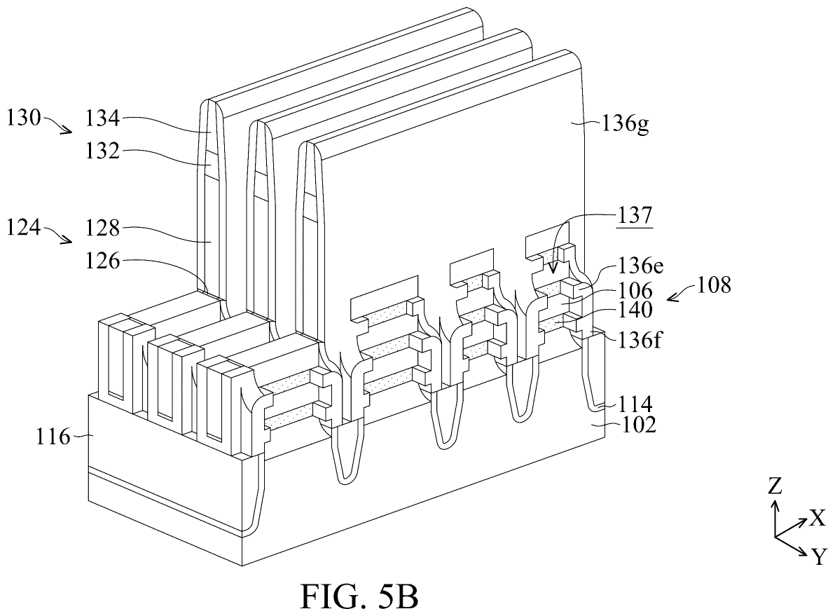

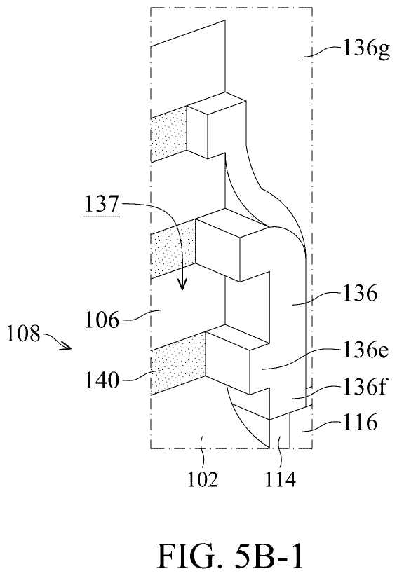

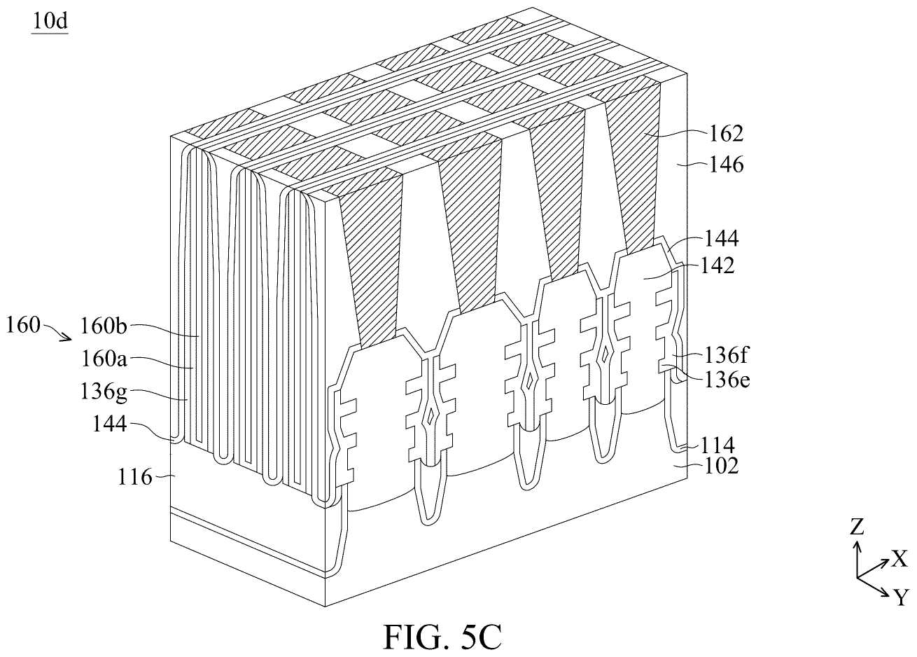

Many variations and/or modifications may be made to the embodiments of the disclosure. FIGS. 5A-5C are perspective representations of various stages of forming a semiconductor device structure 10d, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 5A and 5A-1 in accordance with some embodiments, the topmost recess 135 is wider than the bottommost recess 135.

The etchant used in the etching process forming the recess 135 may be non-uniform. There may be more etchant at the top portion of the fin structure 112 than at the bottom portion of the fin structure 112. Therefore, the upper first semiconductor material layers 104 may be recessed more than the lower first semiconductor material layers 104, and the upper recess 135 may be wider than the lower recess 135.

Afterwards, the first inner spacers 136e formed in the recesses 135, as shown in FIGS. 5B and 5B-1 in accordance with some embodiments. In some embodiments, the bottommost first inner spacer 136e is narrower than the topmost first inner spacer 136e.

Later, the source/drain epitaxial structure 142 are formed over opposite sides of the dummy gate structure 124, and the dummy gate structure 124 are replaced by the gate structure 160, as shown in FIG. 5C in accordance with some embodiments.

By forming multiple inner spacers 136e and 140 between the gate structure 160 and the source/drain epitaxial structure 142, the source/drain epitaxial structure 142 may not be damaged. In addition, the capacitance may be reduced with the first inner spacers 136e. The bottommost first inner spacer 136e may be narrower than the topmost first inner spacer 136e.

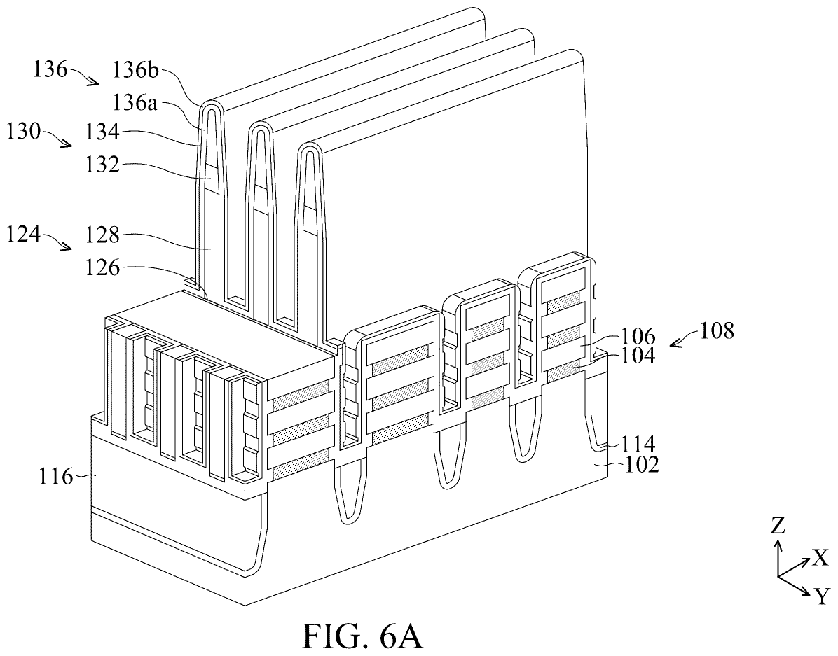

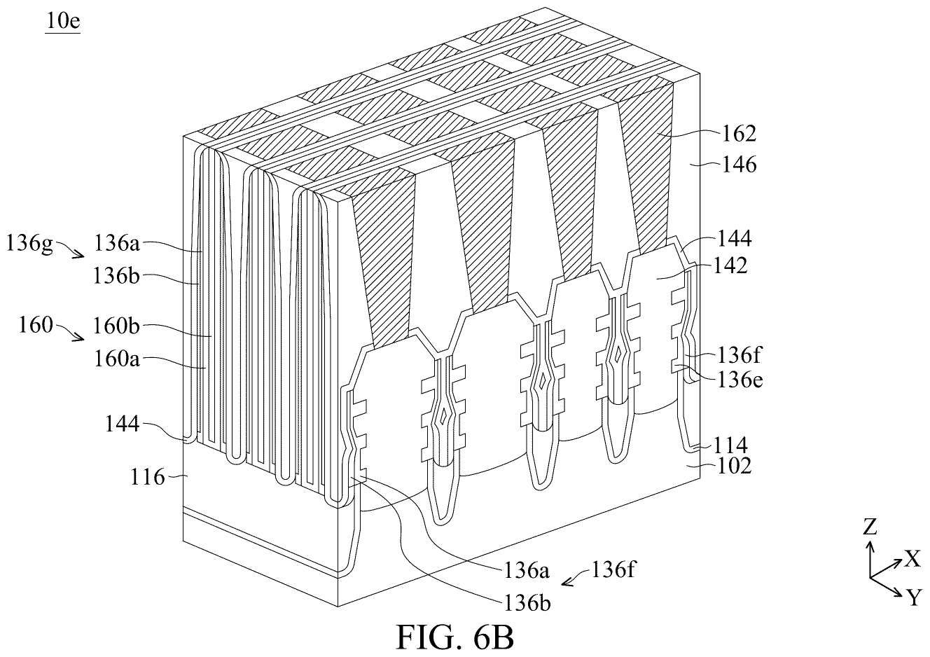

Many variations and/or modifications may be made to the embodiments of the disclosure. FIGS. 6A-6B are perspective representations of various stages of forming a semiconductor device structure 10e, in accordance with some embodiments of the disclosure. Some processes or devices are the same as, or similar to, those described in the embodiments above, and therefore the descriptions of these processes and devices are not repeated herein. The difference from the embodiments described above is that, as shown in FIGS. 6A and 6A-1 in accordance with some embodiments, multiple spacer layers 136a and 136b are formed.

The first spacer layer 136a is formed over the dummy gate structure 124 and the fin structures 112, and also in the recesses 135, as shown in FIG. 6A in accordance with some embodiments. Later, the second spacer layer 136b is formed over the first spacer layer 136a, as shown in FIG. 6A in accordance with some embodiments.

In some embodiments, the fin spacer layer 136f has multiple spacer layers 136a and 136b, as shown in FIG. 6A in accordance with some embodiments. In some embodiments, the first inner spacer layer 136e only has a single spacer layer 136a.

Later, the source/drain epitaxial structure 142 are formed over opposite sides of the dummy gate structure 124, and the dummy gate structure 124 are replaced by the gate structure 160, as shown in FIG. 6B in accordance with some embodiments.

The first spacer layer 136a and the second spacer layer 136b may be made of silicon oxide, silicon nitride, silicon oxynitride, silicon carbon oxynitride, other dielectric materials, or a combination thereof. In some embodiments, the hardness of the second spacer layer 136b is greater than the hardness of the first spacer layer 136a. The second spacer layer 136b may be more etching resistant than the first spacer layer 136a.

It should be noted that, although there are two layers of the spacer layers 136 shown in FIGS. 6A and 6B, the number of the spacer layers 136 are not limited herein, depending on the demand of performance and process.

By forming multiple inner spacers 136e and 140 between the gate structure 160 and the source/drain epitaxial structure 142, the source/drain epitaxial structure 142 may not be damaged. In addition, the capacitance may be reduced with the first inner spacers 136e. The spacer layer 136 may be multiple spacer.

As described previously, the first inner spacer 136e and the second inner spacer 140 are formed beside the gate structure 160, therefore the source/drain epitaxial structure 142 may not be damaged, and the capacitance may be reduced. In some embodiments as shown in FIG. 3, the dummy gate structure 124 is formed by multiple etching steps. In some embodiments as shown in FIG. 4, the extending portions 136e formed over the fin spacer 136f are removed before forming the source/drain epitaxial structure 142. In some embodiments as shown in FIG. 5, the topmost inner spacer 136e is wider than the bottommost inner spacer 136e. In some embodiments as shown in FIG. 6, multiple spacers layers 136a and 136b are formed over the gate structure 160 and the fin structures 112.

Embodiments of a semiconductor device structure and a method for forming the same are provided. Extra inner spacers formed over opposite sides of the original inner spacers may prevent the source/drain epitaxial structure from being damaged, and also may reduce the capacitance.

In some embodiments, a method for forming a semiconductor device structure is provided. The method for forming a semiconductor device structure includes forming fin structures with a stack of alternating first semiconductor layers and second semiconductor layers over a substrate. The method for forming a semiconductor device structure also includes forming a gate structure across the fin structure. The method for forming a semiconductor device structure also includes recessing the first semiconductor layers to form first openings between the second semiconductor layers. The method for forming a semiconductor device structure also includes forming first inner spacers in the first openings. The method for forming a semiconductor device structure also includes removing the fin structures exposed from the gate structure to form a source/drain opening. The method for forming a semiconductor device structure also includes recessing the first semiconductor layers to form second openings between the second semiconductor layers. The method for forming a semiconductor device structure also includes forming second inner spacers in the second openings.

In some embodiments, a method for forming a semiconductor device structure is provided. The method for forming a semiconductor device structure includes forming a fin structure with a stack of alternating channel layers and sacrificial layers. The fin structure is longitudinally oriented along a first direction over a substrate. The method for forming a semiconductor device structure also includes forming a dummy gate structure longitudinally oriented along a second direction across the fin structure. The first direction is perpendicular to the second direction. The method for forming a semiconductor device structure also includes recessing the sacrificial layers in the second direction. The method for forming a semiconductor device structure also includes depositing a first spacer layer covering the fin structure and the dummy gate structure. The method for forming a semiconductor device structure also includes etching the fin structure beside the dummy gate structure and the first spacer layer to form first inner spacers covering the sacrificial layers in the second direction. The method for forming a semiconductor device structure also includes recessing the sacrificial layers in the first direction. The method for forming a semiconductor device structure also includes forming second inner spacers covering the sacrificial layers in the first direction.

In some embodiments, a semiconductor device structure is provided. The semiconductor device structure includes nanostructures formed over a substrate. The semiconductor device structure also includes source/drain epitaxial structures attached to opposite sides of the nanostructures in a first direction. The semiconductor device structure also includes a gate structure wrapped around the nanostructures and longitudinally oriented along a second direction that is different from the first direction. The semiconductor device structure also includes first inner spacers and second inner spacers formed between the gate structure and the source/drain epitaxial structures. The first inner spacers cover opposite sidewalls of the second inner spacers in the second direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming fin structures with a stack of alternating first semiconductor layers and second semiconductor layers over a substrate;
forming a gate structure across the fin structure;
recessing the first semiconductor layers to form first openings between the second semiconductor layers;
forming first inner spacers in the first openings;
removing the fin structures exposed from the gate structure to form a source/drain opening;
recessing the first semiconductor layers to form second openings between the second semiconductor layers; and
forming second inner spacers in the second openings.

2. The method for forming the semiconductor device structure as claimed in claim 1, wherein a top portion of the spacer layer is removed when removing the fin structures exposed from the gate structure.

3. The method for forming the semiconductor device structure as claimed in claim 1, wherein a portion of the first inner spacers are exposed from the source/drain opening.

4. The method for forming the semiconductor device structure as claimed in claim 3, further comprising:
removing the lower first inner spacers exposed from the source/drain opening.

5. The method for forming the semiconductor device structure as claimed in claim 1, further comprising:
trimming the gate structure after forming the first openings.

6. The method for forming the semiconductor device structure as claimed in claim 1, wherein a topmost first opening is wider than a bottommost first openings.

7. The method for forming the semiconductor device structure as claimed in claim 1, wherein a dielectric constant of the first inner spacers is less than a dielectric constant of the second inner spacers.

8. A method for forming a semiconductor device structure, comprising:
forming a fin structure with alternating stacked channel layers and sacrificial layers and longitudinally oriented along a first direction over a substrate;
forming a dummy gate structure longitudinally oriented along a second direction across the fin structure, wherein the first direction is perpendicular to the second direction;
recessing the sacrificial layers in the second direction;
depositing a first spacer layer covering the fin structure and the dummy gate structure;
etching the fin structure beside the dummy gate structure and the first spacer layer to form first inner spacers covering the sacrificial layers in the second direction
recessing the sacrificial layers in the first direction; and
forming second inner spacers covering the sacrificial layers in the first direction.

9. The method for forming the semiconductor device structure as claimed in claim 8, further comprising:
depositing a second spacer layer over the first inner spacers.

10. The method for forming the semiconductor device structure as claimed in claim 9, wherein a hardness of the second spacer layer is greater than a hardness of the first spacer layer.

11. The method for forming the semiconductor device structure as claimed in claim 9, wherein the second inner spacer layer comprises SiO2, SiCO, SiO2:F, SiN, SiCN, oxide, nitrogen, carbon-based materials, or a combination thereof.

12. The method for forming the semiconductor device structure as claimed in claim 8, further comprising:
removing the dummy gate structure;
removing the sacrificial layers; and
forming a gate structure between adjacent spacer layers, adjacent first inner spacers, and adjacent second inner spacers.

13. The method for forming the semiconductor device structure as claimed in claim 8, further comprising:
forming source/drain epitaxial structures beside the gate structure,
wherein the source/drain epitaxial structures are wider than the second inner spacer in the second direction.

14. A semiconductor device structure, comprising:
nanostructures formed over a substrate;
source/drain epitaxial structures attached to opposite sides of the nanostructures in a first direction;
a gate structure wrapped around the nanostructures and longitudinally oriented along a second direction that is different from the first direction; and
first inner spacers and second inner spacers formed between the gate structure and the source/drain epitaxial structures,
wherein the first inner spacers cover opposite sidewalls of the second inner spacers in the second direction.

15. The semiconductor device structure as claimed in claim 14, wherein a bottommost one of the first inner spacers is narrower than a topmost one of the first inner spacers.

16. The semiconductor device structure as claimed in claim 14, wherein the second inner spacers and the first inner spacers have different widths.

17. The semiconductor device structure as claimed in claim 14, wherein the first inner spacers are wider than the second inner spacers in the second direction in a top view.

18. The semiconductor device structure as claimed in claim 14, wherein a hardness of the first inner spacers is greater than a hardness of the second inner spacers.

19. The semiconductor device structure as claimed in claim 14, wherein the gate structure has a tip portion sandwiched between one of the first inner spacers and one of the second inner spacer in the second direction.

20. The semiconductor device structure as claimed in claim 14, wherein each of the first inner spacers has a width in a range of about 2 nm to about 5 nm.
